(19) United States
(12) Patent Application Publication
(10) Pub. No.: US 2023/0402994 A1
(43) Pub. Date: Dec. 14, 2023

(54) PEIZOELECTRIC ELEMENT AND PIEZOELECTRIC DEVICE

(71) Applicant: KYOCERA Corporation, Kyoto-shi (JP)

(72) Inventors: Tomoki MURAYAMA, Kyoto-shi (JP); Hayato TANAKA, Kyoto-shi (JP); Hitoshi YOSHIDA, Kyoto-shi (JP)

(73) Assignee: KYOCERA Corporation, Kyoto-shi (JP)

(21) Appl. No.: 18/450,827

(22) Filed: Aug. 16, 2023

Related U.S. Application Data
(63) Continuation of application No. PCT/JP2022/001322, filed on Jan. 17, 2022.

(30) Foreign Application Priority Data
Feb. 26, 2021 (JP) 2021-030158

(51) Int. Cl. H03H 9/19

(52) U.S. Cl. CPC H03H 9/19

(57) ABSTRACT

A piezoelectric element includes a vibration portion, a holding portion, excitation electrodes, mounted electrodes, and wiring electrodes. A vibration main surface and a holding main surface are on the same plane. A holding main surface includes a fixing portion configured to be in contact with an element mounting member. The mounted electrodes are located side by side on the fixing portion. An inner side edge of the mounted electrode and an inner side edge of the wiring electrode are connected in a straight line. An inner side edge of the mounted electrode and an inner side edge of the wiring electrode are connected in a straight line.

### TECHNICAL FIELD

The present disclosure relates to a piezoelectric element and a piezoelectric device including the piezoelectric element. Examples of piezoelectric devices include crystal resonators and crystal oscillators.

### TECHNICAL BACKGROUND

A piezoelectric element that operates in a thickness-shear vibration mode is known as a type of the piezoelectric element (for example, Patent Literature 1). This piezoelectric element includes an AT-cut crystal piece having main surfaces and excitation electrodes of metal film patterns formed on both of the main surfaces. When an alternating voltage is applied to the excitation electrodes of this piezoelectric element, a thickness-shear vibration occurs in part of the crystal piece between the excitation electrodes.

A piezoelectric device utilizes the piezoelectric effect and the inverse piezoelectric effect of a piezoelectric element to generate a specified oscillation frequency. A typical piezoelectric device has a structure in which a piezoelectric element is contained in a package and hermetically encapsulated within by a lid.

### CITATION LIST

### Patent Literature

Patent Literature 1: Japanese Unexamined Patent Application Publication No. 2018-56860

### SUMMARY

In the present disclosure, a piezoelectric element includes a vibration portion, a holding portion, a pair of excitation electrodes, a pair of mounted electrodes, and a pair of wiring electrodes. The vibration portion is approximately quadrangular in plan view and includes a pair of vibration main surfaces. The holding portion is thicker than the vibration portion, located along at least one edge side of the vibration portion in plan view and integrated with the vibration portion, and includes a pair of holding main surfaces. The pair of excitation electrodes are each located on a corresponding one of the pair of vibration main surfaces. The pair of mounted electrodes are each located on a corresponding one of the pair of holding main surfaces. The pair of wiring electrodes each electrically connects a corresponding one of the pair of excitation electrodes and a corresponding one of the pair of mounted electrodes. One of the pair of vibration main surfaces and one of the pair of holding main surfaces are on the same plane. The other of the pair of holding main surfaces includes a fixing portion configured to be in contact with an element mounting member. The pair of mounted electrodes are located side by side on the fixing portion. When an inner peripheral edge of each of the pair of mounted electrodes is defined as an inner side edge and an inner peripheral edge of each of the pair of wiring electrodes is defined as an inner side edge, the inner side edge of each of the mounted electrodes and the inner side edge of a corresponding one of the wiring electrodes are connected in a straight line.

In the present disclosure, a piezoelectric device includes the piezoelectric element according to the present disclosure, an element mounting member on which the piezoelectric element is located, and a lid, together with the element mounting member, hermetically encapsulating the piezoelectric element.

### BRIEF DESCRIPTION OF THE DRAWINGS

FIG. 1A is a plan view of a piezoelectric element of Embodiment 1.

FIG. 1B is a view seen through the back side of the piezoelectric element in FIG. 1A.

FIG. 1C is a sectional view taken along line Ic-Ic in FIG. 1A.

FIG. 2 is a perspective view of the piezoelectric element of Embodiment 1.

FIG. 3A is a plan view of a piezoelectric element of Embodiment 2.

FIG. 3B is a view seen through the back side of the piezoelectric element in FIG. 3A.

FIG. 3C is a sectional view taken along line IIIc-IIIc in FIG. 3A.

FIG. 4A is a plan view of a first example of a piezoelectric element of Embodiment 3.

FIG. 4B is a plan view of a second example of the piezoelectric element of Embodiment 3.

FIG. 4C is a plan view of a third example of the piezoelectric element of Embodiment 3.

FIG. 4D is a plan view of a fourth example of the piezoelectric element of Embodiment 3.

FIG. 4E is a plan view of a fifth example of the piezoelectric element of Embodiment 3.

FIG. 4F is a plan view of a sixth example of the piezoelectric element of Embodiment 3.

FIG. 4G is a plan view of a seventh example of the piezoelectric element of Embodiment 3.

FIG. 4H is a plan view of an eighth example of the piezoelectric element of Embodiment 3.

FIG. 4I is a plan view of a ninth example of the piezoelectric element of Embodiment 3.

FIG. 5A is a perspective view of a piezoelectric device of Embodiment 4.

FIG. 5B is a sectional view taken along line Vb-Vb in FIG. 5A.

FIG. 5C is a perspective view of part of a piezoelectric device of Embodiment 5.

FIG. 6A is a schematic plan view of a first example of a holding portion in Embodiment 1.

FIG. 6B is a schematic plan view of a second example of the holding portion in Embodiment 1.

FIG. 6C is a schematic plan view of a third example of the holding portion in Embodiment 1.

FIG. 6D is a schematic plan view of a fourth example of the holding portion in Embodiment 1.

FIG. 7A is a plan view of a piezoelectric element of a comparative example.

FIG. 7B is a view seen through the back side of the piezoelectric element in FIG. 7A.

FIG. 7C is a sectional view taken along line VIIc-VIIc in FIG. 7A.

FIG. 8 is a perspective view of the piezoelectric element of the comparative example.

### DETAILED DESCRIPTION

The following describes configurations for implementing the present disclosure (hereinafter denoted as “embodiments”) with reference to the attached drawings. Note that in the present specification and the drawings, substantially the same constituents are denoted by the same reference signs, and repetitive description thereof is omitted. The shapes in the drawings are depicted to enable easier understanding for those skilled in the art; hence they do not necessarily correspond to actual dimensions and ratios.

### Embodiment 1

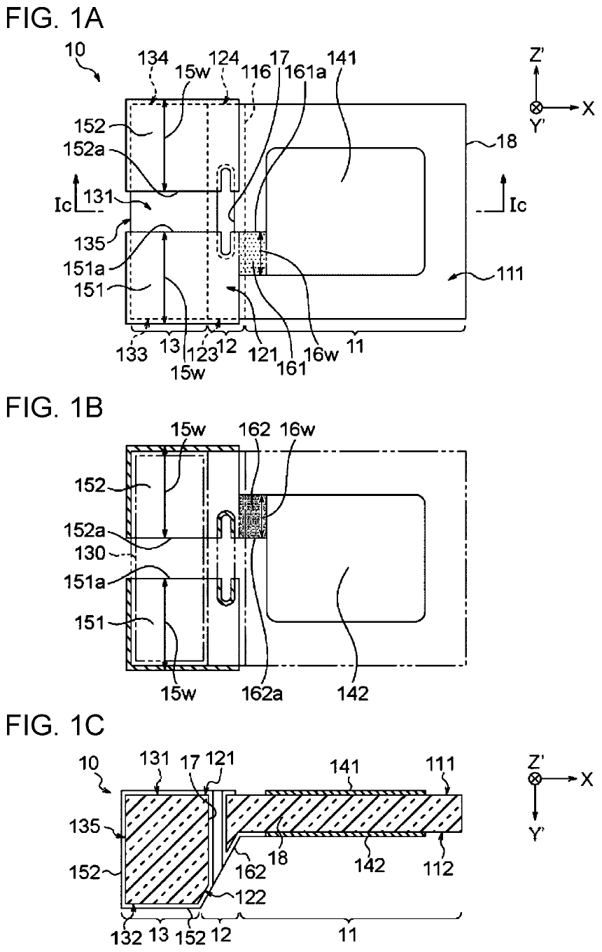

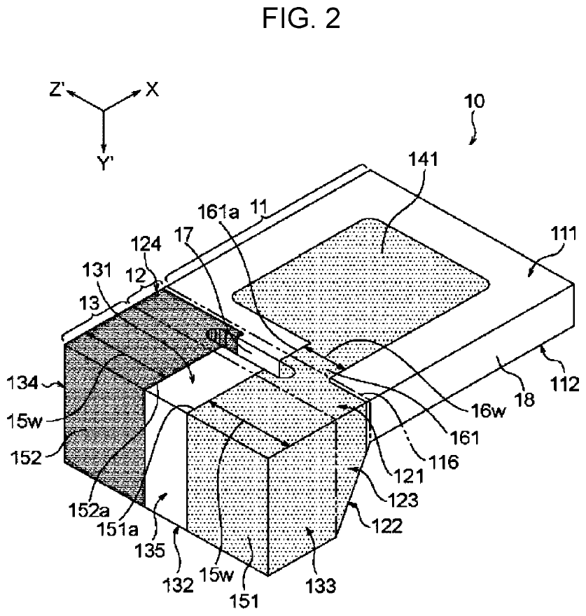

FIG. 1A is a plan view of a piezoelectric element of Embodiment 1. FIG. 1B is a view seen through the back side of the piezoelectric element in FIG. 1A. FIG. 1C is a sectional view taken along line Ic-Ic in FIG. 1A. FIG. 2 is a perspective view of the piezoelectric element of Embodiment 1. The following description will be made mainly with reference to these drawings.

Embodiment 1 relates to a piezoelectric element. A pair of surfaces having a relationship of front and back are denoted as “main surfaces”, the surfaces located between the pair of main surfaces are denoted as “side surfaces”, and dimensions in the direction perpendicular to the main surfaces are denoted as “thickness”. The Cartesian coordinate system XYZ including the crystal axes of the crystal, the X-axis, the Y-axis, and the Z-axis, is rotated around the X-axis by 30° or more and 50° or less, and the resultant coordinate system is defined as a Cartesian coordinate system XY′Z′. The “width” of an electrode denotes the dimension of the electrode in the direction perpendicular to the current flow in plan view.

A piezoelectric element 10 of Embodiment 1 has an approximately quadrangular shape in plan view and includes a vibration portion 11 including a pair of vibration main surfaces 111 and 112, a holding portion 13 thicker than the vibration portion 11, located along at least one edge 116 (FIG. 1A) side of the vibration portion 11 in plan view and integrated with the vibration portion 11, and including a pair of holding main surfaces 131 and 132, a pair of excitation electrodes 141 and 142 located on the pair of vibration main surfaces 111 and 112, a pair of mounted electrodes 151 and 152 located on the pair of holding main surfaces 131 and 132, and a pair of wiring electrodes 161 and 162 electrically connecting the pair of excitation electrodes 141 and 142 and the pair of mounted electrodes 151 and 152. One (the vibration main surface 111) of the pair of vibration main surfaces 111 and 112 and one (the holding main surface 131) of the pair of holding main surfaces 131 and 132 are on the same plane. The other (the holding main surface 132) of the pair of holding main surfaces 131 and 132 includes a fixing portion 130 (FIG. 1B) configured to be in contact with an element mounting member. The pair of mounted electrodes 151 and 152 are located side by side on the fixing portion 130. The inner peripheral edges of the pair of mounted electrodes 151 and 152 and the pair of wiring electrodes 161 and 162 are defined as inner side edges. Here, as illustrated in FIG. 1A, the inner side edge 151a of the mounted electrode 151 and the inner side edge 161a of the wiring electrode 161 are connected in a straight line. As illustrated in FIG. 1B, the inner side edge 152a of the mounted electrode 152 and the inner side edge 162a of the wiring electrode 162 are connected in a straight line. In FIGS. 1A and 1B, the wiring electrodes 161 and 162 are highlighted with dots.

The above constituents may be configured as described below. The inner side edges 151a and 152a of the mounted electrodes 151 and 152 extend from a vibration portion 11 side to a peripheral end (a holding side surface 135) of the holding portion 13 in straight lines. The holding portion 13 further includes a pair of holding side surfaces 133 and 134 located between the pair of holding main surfaces 131 and 132. One (the mounted electrode 151) of the pair of mounted electrodes 151 and 152 extends from one (the holding main surface 131) of the pair of holding main surfaces 131 and 132 via one (the holding side surface 133) of the pair of holding side surfaces 133 and 134 to the other (the holding main surface 132) of the pair of holding main surfaces 131 and 132. The other (the mounted electrode 152) of the pair of mounted electrodes 151 and 152 extends from the one (the holding main surface 131) of the pair of holding main surfaces 131 and 132 via the other (the holding side surface 134) of the pair of holding side surfaces 133 and 134 to the other (the holding main surface 132) of the pair of holding main surfaces 131 and 132.

The configuration of the piezoelectric element 10 will be described further in detail.

The vibration portion 11 has an approximately quadrangular shape in plan view. This “approximately quadrangular shape” includes a square, a rectangle (an oblong shape), and also a rectangular shape with the four corners rounded. The vibration main surface 111 and the holding main surface 131 are on the same plane, and the holding portion 13 is thicker than the vibration portion 11. The holding portion 13 includes the two holding side surfaces 133 and 134 parallel to the XY′ plane and the one holding side surface 135 parallel to the Y′Z′ plane.

In Embodiment 1, an inclined portion 12 includes inclined main surfaces 121 and 122 and inclined side surfaces 123 and 124 and is located between the vibration portion 11 and the holding portion 13. The inclined main surface 121 is on the same plane as the vibration main surface 111 and the holding main surface 131, and the inclined main surface 122 is a slope connecting the vibration main surface 112 and the holding main surface 132. The inclined portion 12 includes a through-hole 17 passing through the inclined main surfaces 121 and 122 in the thickness direction. The inclined main surface 122 can be formed by wet etching, when setting the crystal axes of a crystal piece 21 as illustrated in the figures.

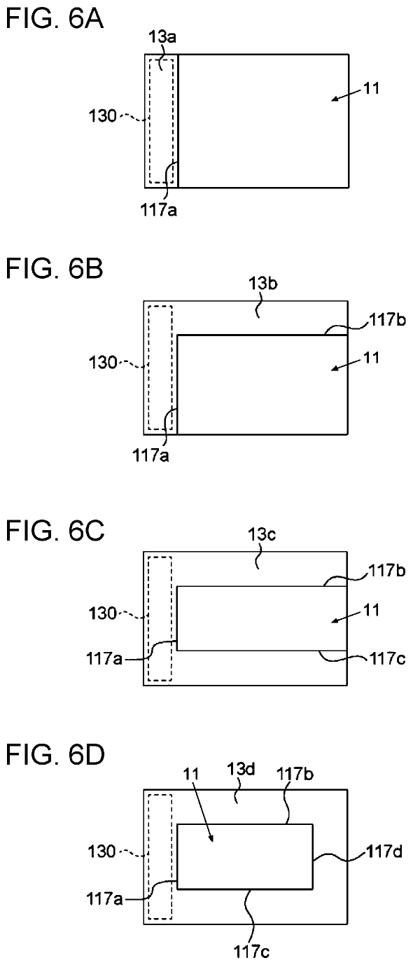

In Embodiment 1, the mounted electrodes 151 and 152 are located on the holding main surface 132 including the fixing portion 130 (FIG. 1B). The holding portion 13 may be formed not only on the one edge 116 (FIG. 1A) side of the vibration portion 11 but also on the two edge sides or three edge sides of the vibration portion 11 or may be formed to surround all the edges of the vibration portion 11. Specific examples of such configurations will be described below with reference to FIGS. 6A to 6D. A holding portion 13a of a first example illustrated in FIG. 6A has an approximately I shape in plan view as in Embodiment 1 and is located on a first edge 117a side of the vibration portion 11. A holding portion 13b of a second example illustrated in FIG. 6B has an approximately L shape in plan view and is located on the first edge 117a side and a second edge 117b side of the vibration portion 11. A holding portion 13c of a third example illustrated in FIG. 6C has an approximately C shape in plan view and is located on the first edge 117a side, the second edge 117b side, and a third edge 117c side of the vibration portion 11. A holding portion 13d of a fourth example illustrated in FIG. 6D has an approximately hollow square shape in plan view and is located on the first edge 117a side, the second edge 117b side, the third edge 117c side, and a fourth edge 117d side of the vibration portion 11. In the first to fourth examples, the holding portions 13a, 13b, 13c, and 13d are thicker than the vibration portion 11. Although the fixing portion 130 is at the same position in each of the holding portions 13a, 13b, 13c, and 13d, the fixing portion 130 may be at a different position in each holding portion. Specifically, the fixing portion 130 may be located at any position in the holding portions 13a, 13b, 13c, and 13d.

The piezoelectric element 10 operates in a thickness-shear vibration mode, and the oscillation frequency (the fundamental frequency) is, for example, 100 MHz or more. The vibration portion 11, the inclined portion 12, and the holding portion 13 are composed of one crystal piece 18. The excitation electrodes 141 and 142, the mounted electrodes 151 and 152, and the wiring electrodes 161 and 162 are metal patterns composed of the same material.

The crystal piece 18 is an AT-cut crystal plate. Specifically, defining the Cartesian coordinate system XY′Z′ in crystal by rotating the Cartesian coordinate system XYZ including the X-axis (the electrical axis), the Y-axis (the mechanical axis), and the Z-axis (the optical axis) is rotated around the X-axis by 30° or more and 50° or less (for example, 35° 15′), a wafer cut out parallel to the XZ′ plane is used as a raw material of the crystal piece 18. The longitudinal direction of the crystal piece 18 is parallel to the X-axis, the lateral direction is parallel to the Z′-axis, and the thickness direction is parallel to the Y′-axis.

Below is an example of the dimensions of the crystal piece 18 and the like. The crystal piece 18 has a length (in the X-axis direction) of 750 to 950 μm and a width (in the Z′-axis direction) of 600 to 800 μm. The holding portion 13 has a thickness (in the Y′-axis direction) of 30 to 50 μm, and the vibration portion 11 has a thickness (in the Y′-axis direction) of approximately 5 to 10 μm. The excitation electrodes 141 and 142 include edges of 250 to 400 μm in length. In this case, the oscillation frequency is approximately 160 to 340 MHz.

The inclined main surface 121 is on the same plane as the vibration main surface 111 and the holding main surface 131, but the inclined main surface 122 is a slope connecting the vibration main surface 112 and the holding main surface 132. In other words, the thickness of the inclined portion 12 decreases as the distance from the holding portion 13 increases. Thus, the stress transmitted from the holding portion 13 to the vibration portion 11 is absorbed or dispersed by the inclined portion 12 (a gentle step). The secondary vibration generated at the vibration portion 11 is gradually attenuated as it approaches the holding portion 13, and thus the influence on the vibration portion 11 of the secondary vibration reflected by the holding portion 13 reduces. Thus, the inclined portion 12 also plays, for example, a role of reducing the equivalent series resistance value.

The through-hole 17 passes through between the vibration portion 11 and the mounted electrodes 151 and 152 in the thickness direction. Thus, the stress transmitted from the holding portion 13 to the vibration portion 11 is absorbed or dispersed by the through-hole 17. In other words, the through hole 17 can reduce the strain generated in the vibration portion 11 when the holding portion 13 is connected to a package. The through-hole 17 plays a role of confining the vibration energy of the vibration portion 11. Thus, the through-hole 17 also plays, for example, a role of reducing the equivalent series resistance value. Since the through-hole 17 is formed in the inclined portion 12, these effects are enhanced by being combined with the effects of the inclined portion 12.

The pair of excitation electrodes 141 and 142 have approximately quadrangular shapes in plan view and are respectively provided approximately at the centers of the vibration main surfaces 111 and 112 of the vibration portion 11. The wiring electrodes 161 and 162, which do not contribute to the excitation but are for connection, extend from the excitation electrodes 141 and 142 to the mounted electrodes 151 and 152. In other words, the excitation electrode 141 is electrically continuous with the mounted electrode 151 via the wiring electrode 161, and the excitation electrode 142 is electrically continuous with the mounted electrode 152 via the wiring electrode 162.

The mounted electrode 151 is provided on the holding main surfaces 131 and 132, on the holding side surfaces 133 and 135, on the inclined main surfaces 121 and 122, on the inclined side surface 123, and in the through-hole 17. The mounted electrode 152 is provided on the holding main surfaces 131 and 132, on the holding side surfaces 134 and 135, on the inclined main surfaces 121 and 122, on the inclined side surface 124, and in the through-hole 17. The excitation electrode 141 and the wiring electrode 161 are provided on a vibration main surface 111 side, and the excitation electrode 142 and the wiring electrode 162 are provided on a vibration main surface 112 side.

The metal patterns forming the excitation electrodes 141 and 142, the mounted electrodes 151 and 152, and the wiring electrodes 161 and 162 are, for example, laminates including a primary layer of chromium (Cr) and a conductive layer of gold (Au). Specifically, the primary layer is on the crystal piece 18, and the conductive layer is on the primary layer. The primary layer plays mainly a role of providing a force for adhering to the crystal piece 18. The conductive layer plays mainly a role of providing electrical conduction.

Formation of a metal film is called film formation. Examples of manufacturing steps of metal patterns include a method including forming photoresist patterns after film formation on a crystal piece, and performing etching on the resultant; a method including forming photoresist patterns on a crystal piece, and performing film formation and a lift off process on the resultant; and a method including covering a crystal piece with metal masks, and performing film formation on the resultant. Film formation is performed by using sputtering, vapor deposition, or the like.

The piezoelectric element 10 can be manufactured, for example, by using a photolithography technique and an etching technique, as follows.

First, corrosion-resistant films are formed on the entire surfaces of an AT-cut crystal wafer, and photoresists are then formed on the corrosion-resistant films. Then, masks including patterns of the outer shape of the crystal piece 18 (including the through-hole 17) and the vibration portion 11 (only for one side) are laid on the photoresists, and parts of the corrosion-resistant films are exposed by exposure and development. Then, wet etching is performed on the corrosion-resistant films in this state. After that, by using the remaining corrosion-resistant films as masks, wet etching is performed on the crystal wafer to form the outer shape of the crystal piece 18 and the vibration portion 11. The outer shape of the crystal piece 18 is formed by double-sided etching, and the vibration portion 11 is formed by single-sided etching. The inclined main surface 122 is also formed in this wet etching.

After that, the remaining corrosion-resistant films are removed from the crystal wafer, and metal films serving as the excitation electrodes 141 and 142 and others are provided on the entire surfaces of the crystal wafer. Then, photoresist masks including patterns of the excitation electrodes 141 and 142 and others are formed on the metal films, and unnecessary metal films are removed by etching to form the excitation electrodes 141 and 142 and others. After that, by removing unnecessary photoresists, a plurality of piezoelectric elements 10 are formed in the crystal wafer. Lastly, the individual piezoelectric elements 10 are separated from this crystal wafer to obtain discrete piezoelectric elements 10.

The piezoelectric element 10 operates as follows. An alternating voltage is applied to the crystal piece 18 via the excitation electrodes 141 and 142. Then, a thickness-shear vibration occurs in the crystal piece 18 such that the vibration main surfaces 111 and 112 are displaced from each other, which generates a specified oscillation frequency. Thus, the piezoelectric element 10 operates to output a signal at a constant oscillation frequency by utilizing the piezoelectric effect and the inverse piezoelectric effect of the crystal piece 18. Here, the thinner the crystal piece 18 (specifically, the vibration portion 11) between the excitation electrodes 141 and 142, the higher the oscillation frequency.

The following describes the operation and the effects of the piezoelectric element 10.
(1) The piezoelectric element 10 is suitable for a higher frequency operation and can have a low equivalent series resistance value. The reason is as follows.

In Embodiment 1, the vibration main surface 111 and the holding main surface 131 are on the same plane, and the holding portion 13 is thicker than the vibration portion 11. Accordingly, a structure can be achieved in which the thick holding portion 13 supports the thin vibration portion 11. Hence, even if the vibration portion 11 is thinner to achieve a higher oscillation frequency, the mechanical strength of the piezoelectric element 10 can be maintained. Thus, the piezoelectric element 10 has a structure suitable for a higher frequency operation.

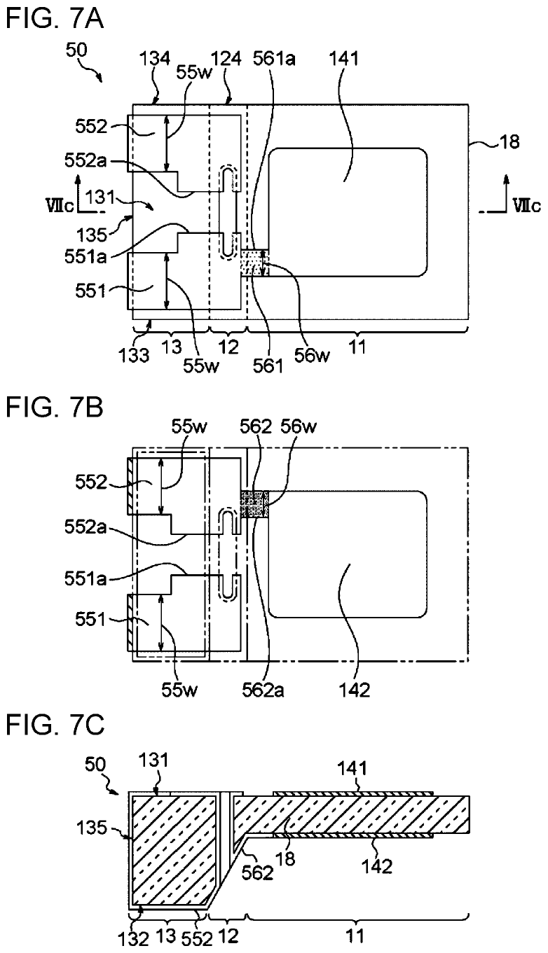

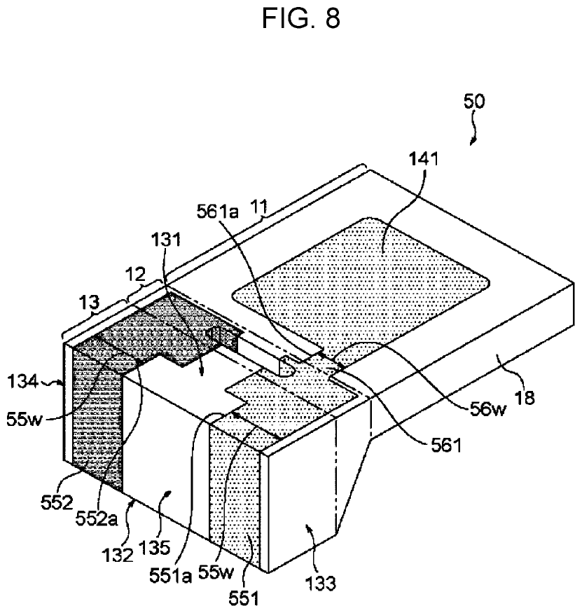

Description will be made in comparison between a piezoelectric element 50 of a comparative example illustrated in FIGS. 7A, 7B, 7C, and 8 and the piezoelectric element 10 of Embodiment 1. The piezoelectric element 50 of the comparative example has the same configuration as that of the piezoelectric element 10 of Embodiment 1 except that the shapes of mounted electrodes 551 and 552 and wiring electrodes 561 and 562 are different from those in Embodiment 1.

In the comparative example, as illustrated in FIG. 7A, an inner side edge 551a of the mounted electrode 551 and an inner side edge 561a of the wiring electrode 561 are connected stepwise As illustrated in FIG. 7B, an inner side edge 552a of the mounted electrode 552 and an inner side edge 562a of the wiring electrode 562 are connected stepwise. In other words, the widths 56w of the wiring electrodes 561 and 562 are narrow. This is because when the widths 56w are wide, vibration can occur in portions of the wiring electrodes 561 and 562 close to the excitation electrodes 141 and 142, and the vibration can leak to the holding portion 13.

However, since the holding portion 13 is thicker than the vibration portion 11, the thickness difference reinforces the confinement of vibration energy. Accordingly, the vibration leakage from the vibration portion 11 to the holding portion 13 may be small. Hence, in Embodiment 1, the inner side edge 151a of the mounted electrode 151 and the inner side edge 161a of the wiring electrode 161 are connected in a straight line, and the inner side edge 152a of the mounted electrode 152 and the inner side edge 162a of the wiring electrode 162 are connected in a straight line. Thus, the widths 16w of the wiring electrodes 161 and 162 are made wide to reduce the equivalent series resistance value. Thus, the piezoelectric element 10 is suitable for a higher frequency operation and can have a low equivalent series resistance value.
(2) In the comparative example, as illustrated in FIGS. 7A and 7B, the inner side edges 551a and 552a of the mounted electrodes 551 and 552 extend stepwise from the vibration portion 11 side to the peripheral end (the holding side surface 135) of the holding portion 13. In other words, the widths 55w of portions of the mounted electrodes 551 and 552 closer to the holding side surface 135 are narrow. This is because when the widths 55w are wide, the mounted electrodes 551 and 552 are closer to each other, and the mounted electrodes 551 and 552 can be electrically short-circuited when the mounted electrodes 551 and 552 are connected to an element mounting member with a conductive adhesive.

However, recent improved positioning accuracy may rarely cause a short circuit due to a conductive adhesive. Hence, in Embodiment 1, the inner side edges 151a and 152a of the mounted electrodes 151 and 152 extend in straight lines from the vibration portion 11 side to the peripheral end (the holding side surface 135) of the holding portion 13 to increase the widths 15w of the portions of the mounted electrodes 151 and 152 close to the holding side surface 135. Accordingly, the equivalent series resistance value can be further reduced.
(3) In the comparative example, as illustrated in FIGS. 7A and 7B, the mounted electrodes 551 and 552 extend from the holding main surface 131 to the holding main surface 132 only via the holding side surface 135. In contrast, in Embodiment 1, the mounted electrodes 151 and 152 extend from the holding main surface 131 to the holding main surface 132 via the holding side surfaces 133, 134, and 135. In other words, the mounted electrodes 151 and 152 cover not only the holding main surfaces 131 and 132 and the holding side surface 135 but also the holding side surfaces 133 and 134. Thus, in Embodiment 1, the effective widths of the mounted electrodes 151 and 152 can be wider than those of the comparative example, which can further reduce the equivalent series resistance value.

### Embodiment 2

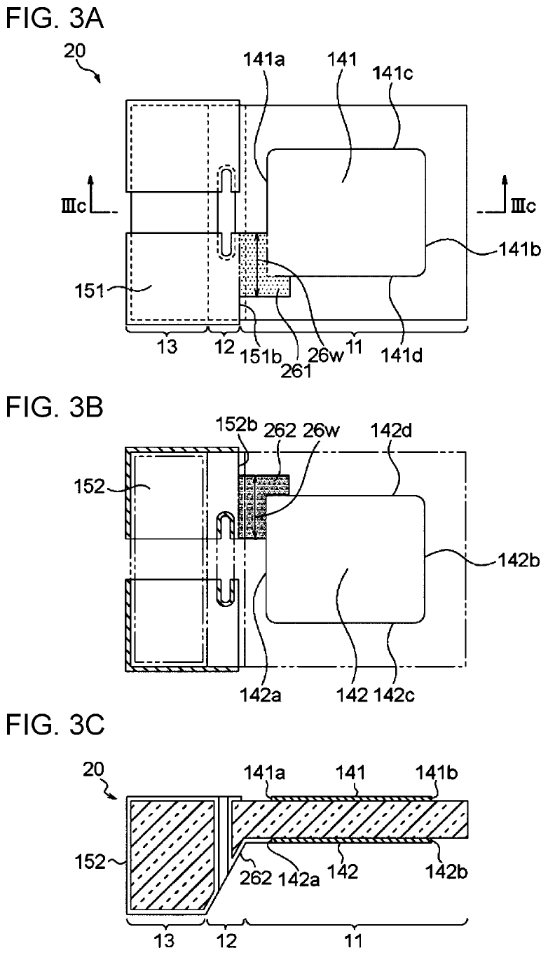

FIG. 3A is a plan view of a piezoelectric element of Embodiment 2. FIG. 3B is a view seen through the back side of the piezoelectric element in FIG. 3A. FIG. 3C is a sectional view taken along line IIIc-IIIc in FIG. 3A. The following description will be made mainly with reference to these drawings.

A piezoelectric element 20 of Embodiment 2 has the same configuration as that of the piezoelectric element 10 of Embodiment 1 (FIGS. 1A and 1B) except that the shapes of the wiring electrodes 261 and 262 are different from those in Embodiment 1. In FIGS. 3A and 3B, the wiring electrodes 261 and 262 are highlighted with dots. Since FIG. 3B is not a bottom view of the piezoelectric element 20 from its back side but a view seen from the front side through the back side of the piezoelectric element 20, the right-left relationship is reversed in the following description.

The pair of excitation electrodes 141 and 142 and the pair of mounted electrodes 151 and 152 have approximately quadrangular shapes including four edges in plan view. Regarding the four edges of the excitation electrodes 141 and 142, the edges on a holding portion 13 side are defined as lower edges 141a and 142a, the edges opposite to the lower edges 141a and 142a are defined as upper edges 141b and 142b, and the right and left edges when the excitation electrodes 141 and 142 are oriented with the upper edges 141b and 142b upward and with the lower edges 141a and 142a downward are defined as pairs of side edges (left edges 141c and 142c and right edges 141d and 142d). Regarding the four edges of the mounted electrodes 151 and 152, the edges on the vibration portion 11 side are defined as upper edges 151b and 152b. In this configuration, the wiring electrode 261 extends from the lower edge 141a and one (the right edge 141d in Embodiment 2) of the pair of side edges of the excitation electrode 141 to the upper edge 151b of the mounted electrode 151. The wiring electrode 262 extends from the lower edge 142a and one (the right edge 142d in Embodiment 2) of the pair of side edges of the excitation electrode 142 to the upper edge 152b of the mounted electrode 152.

The wiring electrodes 161 and 162 (FIGS. 1A and 1B) of Embodiment 1 extend from only the lower edges 141a and 142a (FIGS. 3A and 3B) of the excitation electrodes 141 and 142 to the upper edges 151b and 152b (FIGS. 3A and 3B) of the mounted electrodes 151 and 152. In contrast, the wiring electrodes 261 and 262 of Embodiment 2 extend not only from the lower edges 141a and 142a of the excitation electrodes 141 and 142 but also from the right edges 141d and 142d of the excitation electrodes 141 and 142 toward the upper edges 151b and 152b of the mounted electrodes 151 and 152. Hence, in Embodiment 2, the effective widths 26w of the wiring electrodes 261 and 262 can be wider than those in Embodiment 1, which can further reduce the equivalent series resistance value. The other configuration, operation, and effects of Embodiment 2 are the same as and/or similar to those in Embodiment 1.

### Embodiment 3

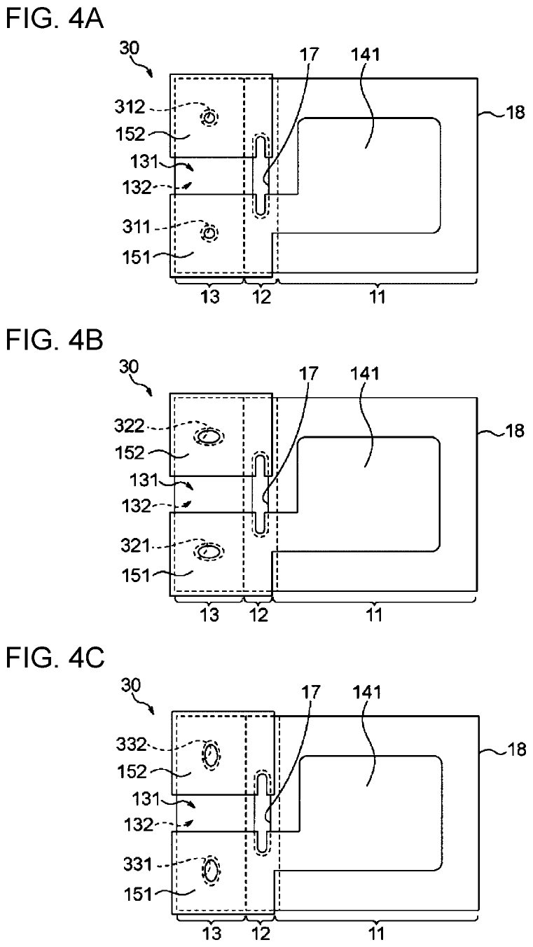

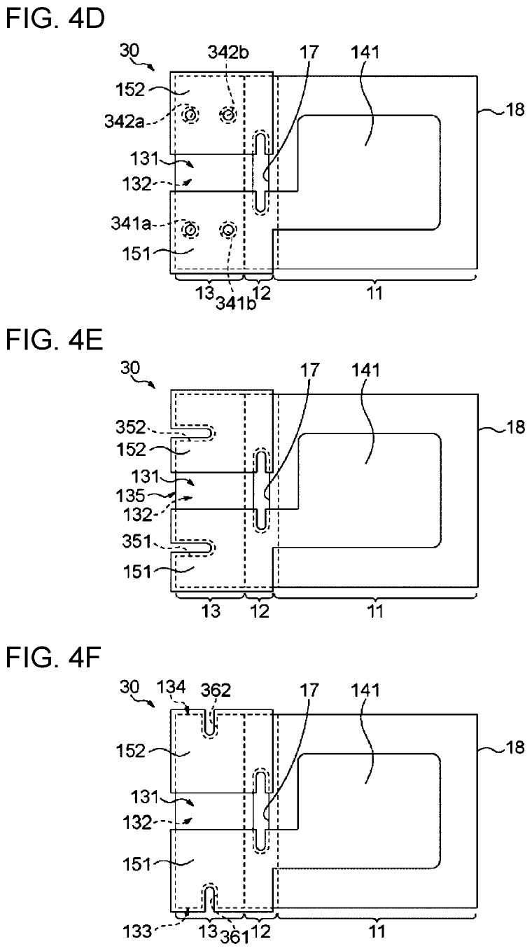

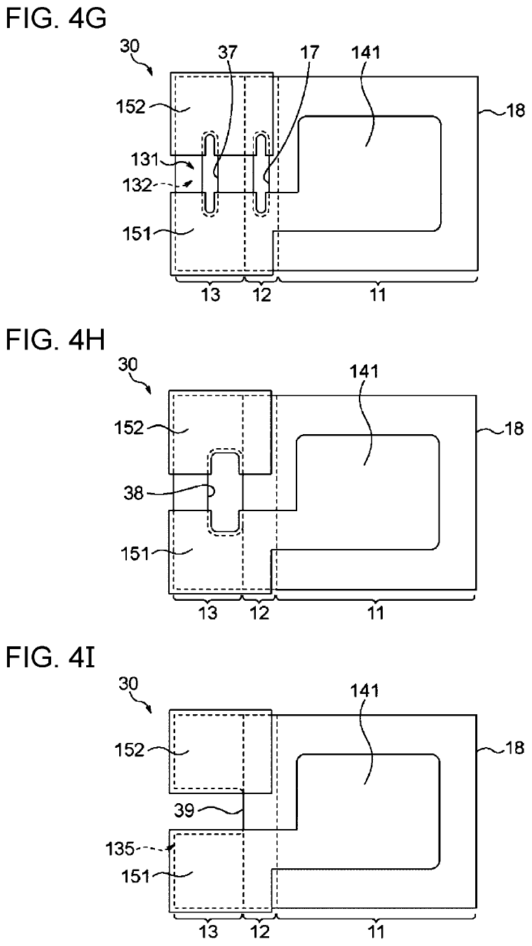

FIGS. 4A to 41 are plan views of first to ninth examples of a piezoelectric element in Embodiment 3.

The following description will be made mainly with reference to these drawings.

A piezoelectric element 30 of Embodiment 3 has approximately the same configuration as that of the piezoelectric element 10 of Embodiment 1 (FIGS. 1A and 1B) except that the holding portion 13 includes a recess or recesses (311 to 39) and that parts of the mounted electrodes 151 and 152 are located in the recess or the recesses (311 to 39).

In the first example illustrated in FIG. 4A, the holding portion 13 includes through-holes 311 and 312 as recesses, and parts of the mounted electrodes 151 and 152 are located in the through-holes 311 and 312, respectively. The through-holes 311 and 312 are circular in plan view, and parts of the mounted electrodes 151 and 152 are formed to be cylindrical on the inner walls of the respective through-holes 311 and 312. Specifically, the mounted electrode 151 is electrically continuous between a holding main surface 131 side and a holding main surface 132 side via the through-hole 311, and the mounted electrode 152 is electrically continuous between the holding main surface 131 side and the holding main surface 132 side via the through-hole 312. Accordingly, this first example can reduce the resistance values of the mounted electrodes 151 and 152, which can further reduce the equivalent series resistance value of the piezoelectric element 30. Note that one of the through-holes 311 and 312 may be included.

In the second example illustrated in FIG. 4B, the holding portion 13 includes through-holes 321 and 322 as recesses, and parts of the mounted electrodes 151 and 152 are located in the through-holes 321 and 322, respectively. The through-holes 321 and 322 are elliptical in plan view. The major axes of the through-holes 321 and 322 are parallel to the longitudinal direction of the piezoelectric element 30, and the minor axes of the through-holes 321 and 322 are parallel to the lateral direction of the piezoelectric element 30. Parts of the mounted electrodes 151 and 152 are formed to be elliptically cylindrical on the inner walls of the respective through-holes 321 and 322. Specifically, the mounted electrode 151 is electrically continuous between the holding main surface 131 side and the holding main surface 132 side via the through-hole 321, and the mounted electrode 152 is electrically continuous between the holding main surface 131 side and the holding main surface 132 side via the through-hole 322. Accordingly, this second example can reduce the resistance values of the mounted electrodes 151 and 152, which can further reduce the equivalent series resistance value of the piezoelectric element 30. Note that one of the through-holes 321 and 322 may be included.

In the third example illustrated in FIG. 4C, the holding portion 13 includes through-holes 331 and 332 as recesses, and parts of the mounted electrodes 151 and 152 are located in the through-holes 331 and 332, respectively. The through-holes 331 and 332 are elliptical in plan view. Contrary to the second example, the major axes of the through-holes 331 and 332 are parallel to the lateral direction of the piezoelectric element 30, and the minor axes of the through-holes 331 and 332 are parallel to the longitudinal direction of the piezoelectric element 30. Parts of the mounted electrodes 151 and 152 are formed to be elliptically cylindrical on the inner walls of the respective through-holes 331 and 332. Specifically, the mounted electrode 151 is electrically continuous between the holding main surface 131 side and the holding main surface 132 side via the through-hole 331, and the mounted electrode 152 is electrically continuous between the holding main surface 131 side and the holding main surface 132 side via the through-hole 332. Accordingly, this third example can reduce the resistance values of the mounted electrodes 151 and 152, which can further reduce the equivalent series resistance value of the piezoelectric element 30. Note that one of the through-holes 331 and 332 may be included.

In the fourth example illustrated in FIG. 4D, the holding portion 13 includes through-holes 341a, 341b, 342a, and 342b as recesses. Part of the mounted electrode 151 is located in the through-holes 341a and 341b, and part of the mounted electrode 152 is located in the through-holes 342a and 342b. The through-holes 341a, 341b, 342a, and 342b are circular in plan view. Part of the mounted electrode 151 is formed to be cylindrical on the inner walls of the through-holes 341a and 341b, and part of the mounted electrode 152 is formed to be cylindrical on the inner walls of the through-holes 342a and 342b. Specifically, the mounted electrode 151 is electrically continuous between the holding main surface 131 side and the holding main surface 132 side via the through-holes 341a and 341b, and the mounted electrode 152 is electrically continuous between the holding main surface 131 side and the holding main surface 132 side via the through-holes 342a and 342b. Accordingly, this fourth example can reduce the resistance values of the mounted electrodes 151 and 152, which can further reduce the equivalent series resistance value of the piezoelectric element 30. Note that either the pair of through-holes 341a and 341b or the pair of through-holes 342a and 342b may be included.

In the fifth example illustrated in FIG. 4E, the holding portion 13 includes cut portions 351 and 352 as recesses, and parts of the mounted electrodes 151 and 152 are located in the cut portions 351 and 352, respectively. The cut portions 351 and 352 are formed in the holding side surface 135, and parts of the mounted electrodes 151 and 152 are formed on the inner walls of the respective cut portions 351 and 352 to be in compressed semi-cylindrical shapes. Specifically, the mounted electrode 151 is electrically continuous between the holding main surface 131 side and the holding main surface 132 side via the cut portion 351, and the mounted electrode 152 is electrically continuous between the holding main surface 131 side and the holding main surface 132 side via the cut portion 352. Accordingly, this fifth example can reduce the resistance values of the mounted electrodes 151 and 152, which can further reduce the equivalent series resistance value of the piezoelectric element 30. Note that one of the cut portions 351 and 352 may be included.

In the sixth example illustrated in FIG. 4F, the holding portion 13 includes cut portions 361 and 362 as recesses, and parts of the mounted electrodes 151 and 152 are located in the cut portions 361 and 362, respectively. The cut portions 361 and 362 are formed in the holding side surfaces 133 and 134, respectively, and parts of the mounted electrodes 151 and 152 are formed on the inner walls of the respective cut portions 361 and 362 to be in compressed semi-cylindrical shapes. Specifically, the mounted electrode 151 is electrically continuous between the holding main surface 131 side and the holding main surface 132 side via the cut portion 361, and the mounted electrode 152 is electrically continuous between the holding main surface 131 side and the holding main surface 132 side via the cut portion 362. Accordingly, this sixth example can reduce the resistance values of the mounted electrodes 151 and 152, which can further reduce the equivalent series resistance value of the piezoelectric element 30. Note that one of the cut portions 361 and 362 may be included.

In the seventh example illustrated in FIG. 4G, the holding portion 13 includes a through-hole 37 as a recess, and parts of the mounted electrodes 151 and 152 are located in the through-hole 37. The through-hole 37 has, for example, the same shape as that of the through-hole 17 in plan view, and parts of the mounted electrodes 151 and 152 are formed on the inner wall of the through-hole 37. Specifically, each of the mounted electrodes 151 and 152 is electrically continuous between the holding main surface 131 side and the holding main surface 132 side via the through-hole 37. Accordingly, this seventh example can reduce the resistance values of the mounted electrodes 151 and 152, which can further reduce the equivalent series resistance value of the piezoelectric element 30.

In the eighth example illustrated in FIG. 4H, the holding portion 13 includes a through-hole 38 as a recess, parts of the mounted electrodes 151 and 152 are located in the through-hole 38, and the through-hole 17 in the seventh example and the like is eliminated. The through-hole 38 is approximately twice as large as the through-hole 17 and is located at a position in the holding portion 13 closer to the inclined portion 12. Parts of the mounted electrodes 151 and 152 are formed on the inner wall of the through-hole 38. Specifically, each of the mounted electrodes 151 and 152 is electrically continuous between the holding main surface 131 side and the holding main surface 132 side via the through-hole 38. Accordingly, this eighth example can reduce the resistance values of the mounted electrodes 151 and 152, which can further reduce the equivalent series resistance value of the piezoelectric element 30.

In the ninth example illustrated in FIG. 4I, the holding portion 13 includes a cut portion 39 as a recess, parts of the mounted electrodes 151 and 152 are located in the cut portion 39, and the through-hole 17 in the seventh example and the like is eliminated. The cut portion 39 is approximately twice as large as the through-hole 17 and extends from the holding side surface 135 through the holding portion 13 to the inclined portion 12. Parts of the mounted electrodes 151 and 152 are formed on the inner wall of the cut portion 39. Specifically, each of the mounted electrodes 151 and 152 is electrically continuous between the holding main surface 131 side and the holding main surface 132 side via the cut portion 39. Accordingly, this ninth example can reduce the resistance values of the mounted electrodes 151 and 152, which can further reduce the equivalent series resistance value of the piezoelectric element 30.

The recesses (311 to 39) of the first to ninth examples are formed by, for example, wet etching, laser processing, ion beam processing, or the like, and the number, positions, and shapes of the recesses are not limited. The other configuration, operation, and effects of Embodiment 3 are the same as and/or similar to those in Embodiments 1 and 2.

### Embodiment 4

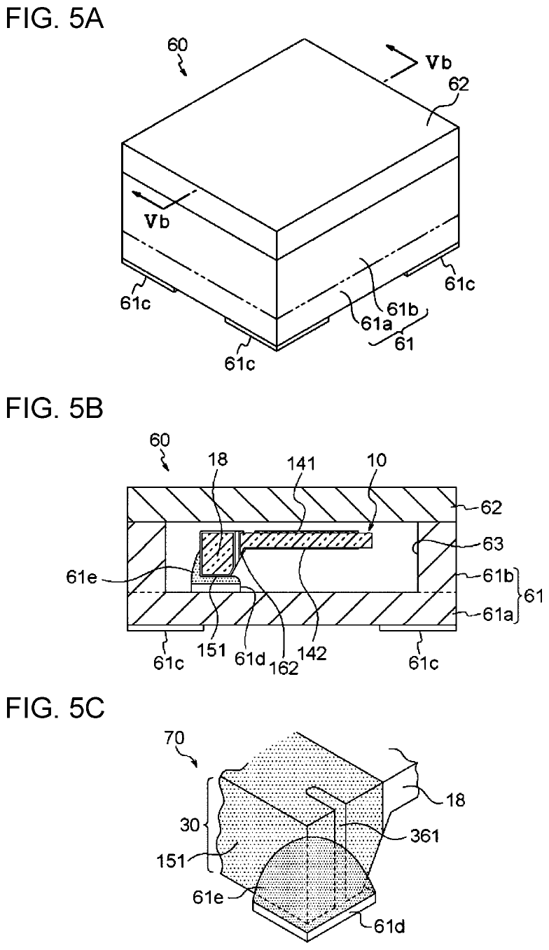

The following describes a piezoelectric device including the piezoelectric element of Embodiment 1 or 2 as Embodiment 4. FIG. 5A is a perspective view of a piezoelectric device of Embodiment 4, and FIG. 5B is a sectional view taken along line Vb-Vb in FIG. 5A. The following description will be made with reference to these figures.

As illustrated in FIGS. 5A and 5B, a piezoelectric device 60 of Embodiment 4 includes the piezoelectric element 10 of Embodiment 1, a base 61 in which the piezoelectric element 10 is located, and a lid 62, together with the base 61, hermetically encapsulating the piezoelectric element 10. The piezoelectric element 10 is connected to the base 61 at the mounted electrodes 151 and 152 with a conductive adhesive 61e. Note that the piezoelectric element 20 of Embodiment 2 may be used instead of the piezoelectric element 10 of Embodiment 1.

The base 61 is also denoted as an element mounting member or a package and includes a substrate 61a and a frame 61b. The space surrounded by the upper surface of the substrate 61a, the inner side surfaces of the frame 61b, and the lower surface of the lid 62 serves as a container 63 for the piezoelectric element 10. The piezoelectric element 10 outputs, for example, a reference signal used in an electronic device or the like.

In other words, the piezoelectric device 60 includes the substrate 61a including a pair of electrode pads 61d on its upper surface and four external terminals 61c on its lower surface, the frame 61b located to extend along the outer peripheral edges of the upper surface of the substrate 61a, the piezoelectric element 10 mounted on the pair of electrode pads 61d via the conductive adhesive 61e, and the lid 62 that, together with the frame 61b, hermetically encapsulates the piezoelectric element 10.

The substrate 61a and the frame 61b are made of, for example, a ceramic material such as an alumina ceramic or a glass ceramic and integrally formed into the base 61. The base 61 and the lid 62 are approximately rectangular in plan view. The external terminals 61c, the electrode pads 61d, and the lid 62 are electrically connected via conductors formed inside or on a side surface of the base 61. More specifically, each of the external terminals 61c is located at the corresponding one of the four corners of the lower surface of the substrate 61a. Two of the external terminals 61c are electrically connected to the piezoelectric element 10, and the remaining two of the external terminals 61c are electrically connected to the lid 62. The external terminals 61c are to be mounted on a print circuit board or the like of an electronic device or the like.

As described earlier, the piezoelectric element 10 includes the crystal piece 18, the excitation electrode 141 formed on the upper surface of the crystal piece 18, and the excitation electrode 142 formed on the lower surface of the crystal piece 18. The piezoelectric element 10 is joined to the electrode pads 61d via the conductive adhesive 61e and plays a role of oscillating to generate a reference signal for an electronic device or the like by utilizing its stable mechanical vibration and piezoelectric effect.

The electrode pads 61d, which are for mounting the piezoelectric element 10 on the base 61, are paired and adjoin each other along one edge of the substrate 61a. The mounted electrodes 151 and 152 are respectively fixed to the pair of electrode pads 61d in a state where one end of the piezoelectric element 10 is a fixed end and the other end of the piezoelectric element 10 is a free end apart from the upper surface of the substrate 61a. Thus, the piezoelectric element 10 is fixed to the substrate 61a with a cantilever structure.

The conductive adhesive 61e contains, for example, a binder such as a silicone resin and conductive powder added as conductive filler. The lid 62 is made of, for example, an alloy containing at least one selected from the group consisting of iron, nickel, and cobalt. The lid 62 is joined to the frame 61b by seam welding or the like to hermetically seal the container 63 in a vacuum state or in a state filled with nitrogen gas or the like.

The piezoelectric device 60 is configured to be mounted on a surface of a print circuit board included in an electronic device with the bottom surfaces of the external terminals 61c fixed to the print circuit board with soldering, gold (Au) bumps, a conductive adhesive, or the like. The piezoelectric device 60 is used as an oscillation source in various electronic devices such as, for example, a smartphone, a personal computer, a watch, a game console, a communication unit, or an in-vehicle device such as a car navigation system.

Since the piezoelectric device 60 includes the piezoelectric element 10 having a low equivalent series resistance value, the piezoelectric device 60 can provide excellent electric characteristics such as a low electric power consumption and a high Q factor.

### Embodiment 5

The following describes a piezoelectric device including the piezoelectric element of Embodiment 3 as Embodiment 5. FIG. 5C is a perspective view of part of the piezoelectric device according to Embodiment 5. The following description will be made with reference to FIGS. 5C and 4F

A piezoelectric device 70 of Embodiment 5 is different from that of Embodiment 4 in that the piezoelectric device 70 includes the piezoelectric element 30 of the sixth example of Embodiment 3 illustrated in FIG. 4F, and that the conductive adhesive 61e is placed in the cut portions 361 and 362 formed as recesses. FIG. 5C illustrates only the cut portion 361.

In the piezoelectric device 70, entry of the conductive adhesive 61e into the cut portions 361 and 362 not only can further reduce the equivalent series resistance of the piezoelectric element 30 but also increases the area of adhesion of the conductive adhesive 61e, which can improve the bond strength of the piezoelectric element 30. The other configuration, operation, and effects of Embodiment 5 are the same as and/or similar to those in Embodiment 4. Note that the piezoelectric device 70 may include a piezoelectric element 30 of another example of Embodiment 3 instead the piezoelectric element 30 of the sixth example of Embodiment 3.

<Other Information>

Although the present disclosure has been described with reference to the above embodiments, the present disclosure is not limited to these embodiments. The present disclosure includes combinations of the whole or part of the embodiments. The configuration and details of the present disclosure can be modified in various ways that those skilled in the art can understand. For example, lithium tantalate, lithium niobate, piezoelectric ceramic, or the like can be used for the piezoelectric material instead of crystal.

### INDUSTRIAL APPLICABILITY

The present disclosure can be used as a piezoelectric element and a piezoelectric device.

### REFERENCE SIGNS

10, 20, 30, 50 piezoelectric element
11 vibration portion
111, 112 vibration main surface
116 one edge
117a first edge
117b second edge
117c third edge
117d fourth edge
12 inclined portion
121, 122 inclined main surface
123, 124 inclined side surface
13, 13a, 13b, 13c, 13d holding portion
130 fixing portion
131, 132 holding main surface
133, 134, 135 holding side surface
141, 142 excitation electrode
141a, 142a lower edge
141b, 142b upper edge
141c, 142c left edge
141d, 142d right edge
151, 152, 551, 552 mounted electrode
151a, 152a, 551a, 552a inner side edge
151b, 152b upper edge
55w width
161, 162, 261, 262, 561, 562 wiring electrode
161a, 162a, 561a, 562a inner side edge
16w, 26w, 56w width
17 through-hole
18 crystal piece
311, 312, 321, 322, 331, 332, 341a, 341b, 342a, 342b, 37, 38 through-hole (recess)
351, 352, 361, 362, 39 cut portion (recess)
70 piezoelectric device
61 base (element mounting member)
61a substrate
61b frame
61c external terminal
61d electrode pad
61e conductive adhesive
62 lid
63 container

1. A piezoelectric element comprising:
a vibration portion approximately quadrangular in plan view and comprising a pair of vibration main surfaces;
a holding portion thicker than the vibration portion, located along at least one edge side of the vibration portion in plan view and integrated with the vibration portion, and comprising a pair of holding main surfaces;
a pair of excitation electrodes each located on a corresponding one of the pair of vibration main surfaces;
a pair of mounted electrodes each located on a corresponding one of the pair of holding main surfaces; and
a pair of wiring electrodes each electrically connecting a corresponding one of the pair of excitation electrodes and a corresponding one of the pair of mounted electrodes, wherein
one of the pair of vibration main surfaces and one of the pair of holding main surfaces are on a same plane,
another of the pair of holding main surfaces comprises a fixing portion configured to be in contact with an element mounting member,
the pair of mounted electrodes are located side by side on the fixing portion, and
an inner peripheral edge of each of the pair of mounted electrodes is an inner side edge and an inner peripheral edge of each of the pair of wiring electrodes is an inner side edge,
the inner side edge of each of the mounted electrodes and the inner side edge of a corresponding one of the wiring electrodes are connected in a straight line.

2. The piezoelectric element according to claim 1, wherein
the inner side edge of each of the mounted electrodes extends in a straight line from a vibration portion side to a peripheral end of the holding portion.

3. The piezoelectric element according to claim 1, wherein
the holding portion further comprises a pair of holding side surfaces located between the pair of holding main surfaces,
one of the pair of mounted electrodes extends from one of the pair of holding main surfaces to another of the pair of holding main surfaces via one of the pair of holding side surfaces, and
another of the pair of mounted electrodes extends from the one of the pair of holding main surfaces to the other of the pair of holding main surfaces via another of the pair of holding side surfaces.

4. The piezoelectric element according to claim 1, wherein
each of the pair of excitation electrodes and the pair of mounted electrodes has an approximately quadrangular shape comprising four edges in plan view, and
an edge of the four edges of each of the excitation electrodes on a holding portion side is defined as a lower edge, an edge of the four edges of each of the excitation electrodes opposite to the lower edge is defined as an upper edge, and right and left edges of the four edges of each of the excitation electrodes when the excitation electrode is oriented with the upper edge upward and with the lower edge downward are defined as a pair of side edges, and
an edge of the four edges of each of the mounted electrodes on a vibration portion side is an upper edge,
each of the wiring electrodes extends from the lower edge and one of the pair of side edges of a corresponding one of the excitation electrodes to the upper edge of a corresponding one of the mounted electrodes.

5. The piezoelectric element according to claim 1, wherein
the holding portion comprises a recess, and
part of each of the mounted electrodes is located in the recess.

6. A piezoelectric device comprising:
the piezoelectric element according to claim 1;
an element mounting member on which the piezoelectric element is located; and
a lid, together with the element mounting member, hermetically encapsulating the piezoelectric element.

7. A piezoelectric device comprising:
the piezoelectric element according to claim 5;
an element mounting member on which the piezoelectric element is located; and
a lid, together with the element mounting member, hermetically encapsulating the piezoelectric element, wherein
the mounted electrodes of the piezoelectric element are connected to the element mounting member with a conductive adhesive, and
part of the conductive adhesive is placed in the recess.
